(19) United States
(12) Patent Application Publication
(10) Pub. No.: US 2002/0099993 A1
(43) Pub. Date: Jul. 25, 2002

(54) Semiconductor testing apparatus and method

(76) Inventor: Satoshi Ikeda, Kanagawa (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/052,736

(22) Filed: Jan. 23, 2002

(30) Foreign Application Priority Data
Jan. 24, 2001 (JP) P2001-015332

(51) Int. Cl. G01R 31/28

(52) U.S. Cl. 714/738

(57) ABSTRACT

Disclosed are semiconductor testing apparatus and method for changing the cycle period of a specific address test pattern in testing a semiconductor device. The semiconductor testing apparatus includes test pattern memory means adapted for storing and managing test pattern data in accordance with addresses, and outputting the test pattern specified by the desired address; test pattern generation means for generating a test pattern signal on the basis of the test pattern outputted from the memory means; and control means for controlling the test pattern memory means and the test pattern generation means in such a manner that the test pattern signal based on the test pattern data of the desired address can be generated at a predetermined timing conforming with the set information.

### BACKGROUND OF THE INVENTION

The present invention relates to an apparatus and a method for testing a semiconductor, and more particularly to those for testing a semiconductor device by first supplying an input signal of a test pattern to the semiconductor device and then comparing the output signal from the semiconductor device with a predetermined expected value.

The functions and performance of a semiconductor device such as a large-scale integrated circuit (LSI) are measured by the use of a semiconductor testing apparatus such as an IC tester or the like.

Now an explanation will be given on a testing procedure executed by an IC tester for measuring the functional operation of a semiconductor device. FIG. 6 is a conceptual diagram of a testing procedure in an IC tester. First, description of timings, signals and so forth is performed in conformity with the language of the IC tester by the use of a computer terminal 300 of a work station or the like, thereby generating a desired test pattern 400. The test pattern 400 thus generated is supplied to an IC tester 200. Subsequently the IC tester 200 supplies an input signal, which is based on the test pattern 400, to the semiconductor device to be tested, and observes the output signal and so forth obtained therefrom to consequently conduct a measurement.

FIG. 7 is a timing chart of a test pattern in an exemplary conventional IC tester. The entire test pattern is composed substantially of a data input portion (or write portion) from an input pin and a data output portion (or read portion) from an output pin. Fundamentally, this composition is not changed regardless of whether the semiconductor device is a memory product or a logic product. In the conventional IC tester, the operation frequency throughout the entire pattern addresses is maintained at a fixed value. That is, the cycle period rate to execute one cycle of any pattern address is fixed throughout the entire pattern addresses. In FIG. 7, there is shown an extraction out of the entire pattern addresses, ranging from an (N)-th cycle portion to an (N+4)-th cycle portion. Each cycle period rate (RATE 1) to determine the operation frequency is constant, and the frequency at which the input and output are performed normally at the minimum rate is the maximum operation frequency in the semiconductor device being tested.

However, in the known semiconductor testing apparatus where the operation frequency is fixed throughout the entire test pattern, there exists a problem that it is impossible to conduct a test of a semiconductor device where the timing of any desired address is specified.

The maximum operation frequency of a semiconductor device is determined by the specific operating state of a specific path on the semiconductor device circuit, i.e., by a specific address portion of the test pattern used on the semiconductor testing apparatus. In testing a semiconductor device, for example, there may arise a case of necessitating a measurement by widening the cycle period of the specific address which determines the maximum operation frequency in a state where the operation frequency of the entire pattern is set to its maximum operation frequency. There may also arise a contrary case of confirming the maximum operating frequency of the specific address portion by first non-limiting the operating frequency of the entire pattern without setting the operating frequency to the maximum thereof and then narrowing the cycle period of the specific address gradually. However, since the operating frequency of the conventional semiconductor testing apparatus is kept constant throughout the entire test pattern, it has been difficult heretofore to realize generation of a test pattern with partial change of the cycle period at the time of generating the pattern and also at the time of changing the test pattern on the semiconductor testing apparatus.

### SUMMARY OF THE INVENTION

The present invention has been accomplished in view of the problems mentioned above. And it is an object of the invention to provide a semiconductor testing apparatus and a testing method capable of changing the cycle period of a specific address test pattern.

According to one aspect of the present invention, in order to solve the above problems, there is provided a semiconductor testing apparatus in which an input signal of a test pattern is supplied to a semiconductor device, and an output signal obtained from the semiconductor device is compared with a prescribed expected value to conduct a test. This apparatus includes test pattern memory means adapted for storing test pattern data of the test pattern, managing the test pattern data in accordance with addresses, and outputting the test pattern specified by the desired address; test pattern generation means for generating a test pattern signal on the basis of the test pattern outputted from the test pattern memory means; and control means for controlling the test pattern memory means and the test pattern generation means in such a manner that the test pattern signal based on the test pattern data of the desired address can be generated at a predetermined timing conforming with the set information.

In the semiconductor testing apparatus of such a structure, the test pattern data generated previously are stored in the test pattern memory means. The test pattern memory means manages the test pattern data in accordance with the addresses, and outputs, in response to control of the control means, the test pattern relevant to the test pattern data of the specified address. The test pattern generation means supplies, in response to control of the control means, a test pattern signal on the basis of the test pattern outputted from the test pattern memory means, and then supplies the test pattern signal to the semiconductor device being tested. The control means controls both the test pattern memory means and the test pattern generation means in such a manner that the timing of generation of the test pattern signal based on the test pattern data of a desired address coincides with the timing that conforms with the predetermined set information. As a result, the timing to generate the test pattern of the desired address in conformity with the set information is controlled to thereby generate a desired test period.

According to another aspect of the present invention, in order to solve the aforementioned problems, there is provided a semiconductor testing method in which an input signal of a test pattern is supplied to a semiconductor device, and an output signal obtained from the semiconductor device is compared with a prescribed expected value to conduct a test. This method has a procedure which includes steps of managing and storing, in accordance with addresses, test pattern data of the test pattern generated previously, then outputting the test pattern of a desired address at a predetermined timing that conforms with the set information, and generating a test pattern signal on the basis of the test pattern data of the desired address outputted at the predetermined timing.

In the semiconductor testing method having such a procedure, the test pattern data representing the test pattern generated previously are stored and managed in accordance with the addresses. And in the test, the test pattern relevant to the stored test pattern data of the desired address is outputted at the predetermined timing that conforms to the set information, thereby generating a test pattern signal based on the test pattern. As a result, the timing to generate the test pattern of the desired address in conformity with the set information is controlled to thereby generate a desired test period.

The above and other objects, features and advantages of the present invention will become apparent from the following description and the appended claims, taken in conjunction with the accompanying drawings in which like parts or elements denoted by like reference symbols.

### BRIEF DESCRIPTION OF THE DRAWINGS

FIG. 1 is a block diagram of a semiconductor testing apparatus representing an embodiment of the present invention;

FIG. 2 is a timing chart of a first test in the semiconductor testing apparatus representing the embodiment of the invention;

FIGS. 3A to 3C are timing charts of a second test in the semiconductor testing apparatus representing the embodiment of the invention;

FIG. 4 is a conceptual diagram of correspondence between a test pattern and an internal circuit of a semiconductor device;

FIG. 5 shows an embodiment of a fault analysis art using the semiconductor testing method of the present invention;

FIG. 6 is a conceptual diagram of a testing procedure in an IC tester; and

FIG. 7 is a timing chart of a test pattern in a conventional IC tester.

### DETAILED DESCRIPTION OF THE PREFERRED EMBODIMENTS

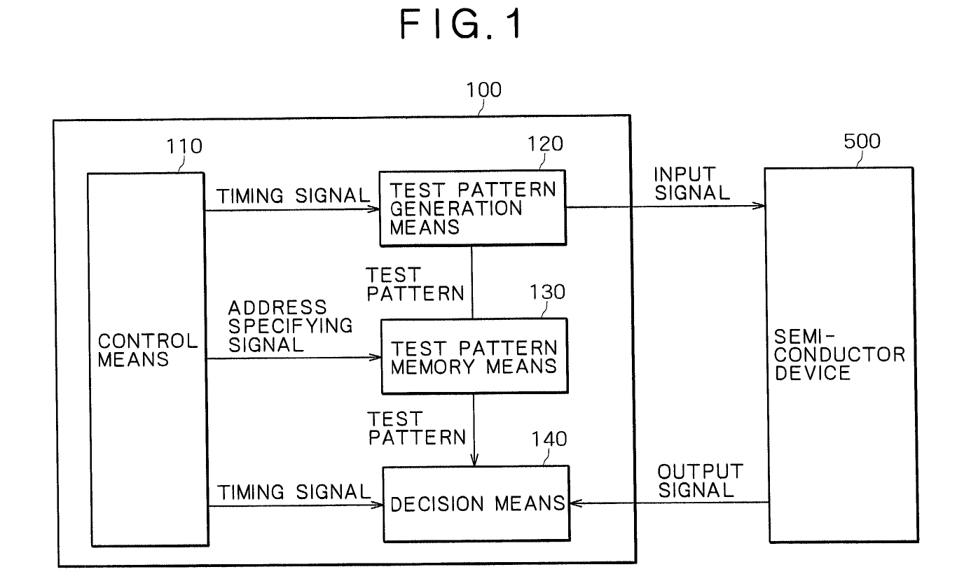

Hereinafter some preferred embodiments of the present invention will be described in detail with reference to the accompanying drawings. FIG. 1 is a block diagram of a semiconductor testing apparatus which represents an embodiment of the present invention.

The semiconductor testing apparatus 100 of the invention includes a control means 110 for controlling both the whole apparatus and a timing to generate a test pattern; a test pattern generation means 120 for generating a test pattern signal; a test pattern memory means 130 for storing the test pattern; and a decision means 140 for deciding an output signal from a semiconductor device 500 to be tested, in which a test of the semiconductor device 500 is conducted. The test pattern used for testing the semiconductor device 500 is generated previously by a computer terminal such as a work station, and is stored in the test pattern memory means 130 in advance to start of a test. The test pattern is composed of test pattern data managed in accordance with the addresses, and the cycle period rate to execute one cycle of any pattern address is predetermined. Normally, the cycle period rate is set to a fixed value.

The control means 110 controls the whole apparatus, and forms an operation reference signal to operate the test pattern. The control means 110 also generates a timing signal to produce a test pattern signal, and further generates an address specifying signal for the test pattern memory means 130 per cycle period. As the control means 110 controls the timings to generate both the timing signal and the address specifying signal in conformity with the set information, the test pattern cycle period for any address can be varied. The set information is transferred to the semiconductor testing apparatus 100 prior to or during the test by some method. In execution of the test, the control means 110 always refers to the latest set information to thereby control the timings to generate the timing signal and the address specifying signal.

The test pattern generation means 120 combines, in each cycle period, a portion of the timing signal outputted from the control means 110 with a portion of the test pattern outputted from the test pattern memory means 130, thereby generating a test pattern signal. The test pattern signal thus obtained is supplied as an input signal to the semiconductor device 500 being tested.

The test pattern memory means 130 previously stores therein the test pattern managed in accordance with addresses, and in response to the address specifying signal received from the control means 110, outputs the required test pattern in each cycle period to the test pattern generation means 120 and the decision means 140.

The decision means 140 substantially includes a high decision circuit and a low decision circuit, and receives an output signal of the semiconductor device 500 being tested. With regard to each individual signal for decision of a high level or a low level, the decision means 140 makes a decision by the use of a portion of the test pattern outputted from the test pattern memory means 130 and a decision timing signal outputted from the control means 110, and then delivers the result of such a decision to an external means. The decision is made by a comparison as to whether the output signal from the semiconductor device 500 coincides with the prescribed expected value.

Now an explanation will be given on the operation of the semiconductor testing apparatus 100 having the above structure and also on the testing method carried out therein. In the test pattern memory means 130 of the semiconductor testing apparatus 100, there are previously stored test pattern data generated in advance by a work station or the like and adapted for testing the semiconductor device 500. The test pattern data are managed in accordance with addresses. And set information for controlling the cycle period to execute the test pattern of each address is also set prior to start of the test.

Upon start of the test, the control means 110 forms an operation reference signal to operate the test pattern, and generates a timing signal to produce a test pattern signal in conformity with the set information, and further generates an address specifying signal per cycle period for the test pattern memory means 130. In response to the address specifying signal received from the control means 110, the test pattern memory means 130 outputs, in each cycle period, a required test pattern to the test pattern generation means 120 and the decision means 140. Subsequently the test pattern generation means 120 combines, in each cycle period, a portion of the timing signal obtained from the control means 110 with a portion of the test pattern outputted from the test pattern memory means 130, thereby generating a test pattern signal. The test pattern signal thus generated is supplied as an input signal to the semiconductor device 500 being tested. The decision means 140 receives the output signal of the semiconductor device 500 being tested, then makes a decision by the use of a portion of the test pattern obtained from the test pattern memory means 130 and the decision timing signal obtained from the control means 110, and outputs the result of such a decision to an external means.

In this manner, as the control means 110 controls the timings to generate the timing signal and the address specifying signal in conformity with the set information, it becomes possible to freely set the test pattern cycle period of any desired address.

Hereinafter the test of the semiconductor device using the semiconductor testing apparatus described above will be explained with reference to a concrete example thereof.

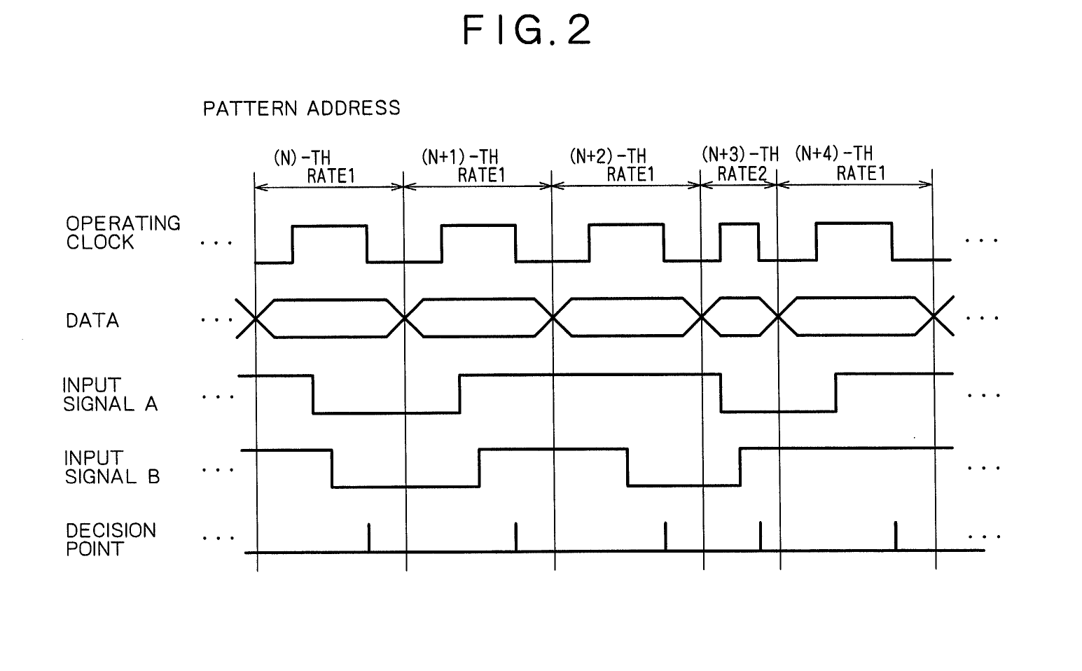

Initially, an explanation will be given on a first test which evaluates a desired subject address by narrowing the cycle period rate of the test pattern relative to the subject address. FIG. 2 is a timing chart of the first test executed in the semiconductor testing apparatus which represents an embodiment of the present invention. This timing chart shows a case of narrowing the cycle period rate where, out of the partial test pattern ranging from an (N)-th address to an (N+4)-th address in an arbitrary address section, an (N+3)-th address is designated as a specific subject address. In this case, the cycle period rate of the entire test pattern is set to a value (RATE 1) lower than the maximum operation frequency and, in conformity with the set information, the rate of the specific subject address only, i.e., the (N+3)-th cycle, is raised to a higher value (RATE 2) As a result, there occurs a state where the timing of each signal only in the specific subject address of the (N+3)-th cycle restricts the operation of the device. Thus, it becomes possible to evaluate the timing power and the margin of the subject address without being affected by the timing of any other address. And the cycle frequency rate of the specific address can be successively narrowed by changing the set information, hence realizing confirmation of the maximum operation frequency in the relevant portion.

In this operation, there exists no limitation in setting the address to narrow the cycle period and the timing thereof in a test by determining a desired address from the beginning in accordance with an object or by narrowing the cycle period rate merely in a portion of the test pattern. And it can be considered with ease that a test may be executed, as an application, by narrowing the cycle period rate of plural addresses as well as that of any specific address. Further, the cycle period rate can be widened also in compliance with requirements, instead of being narrowed.

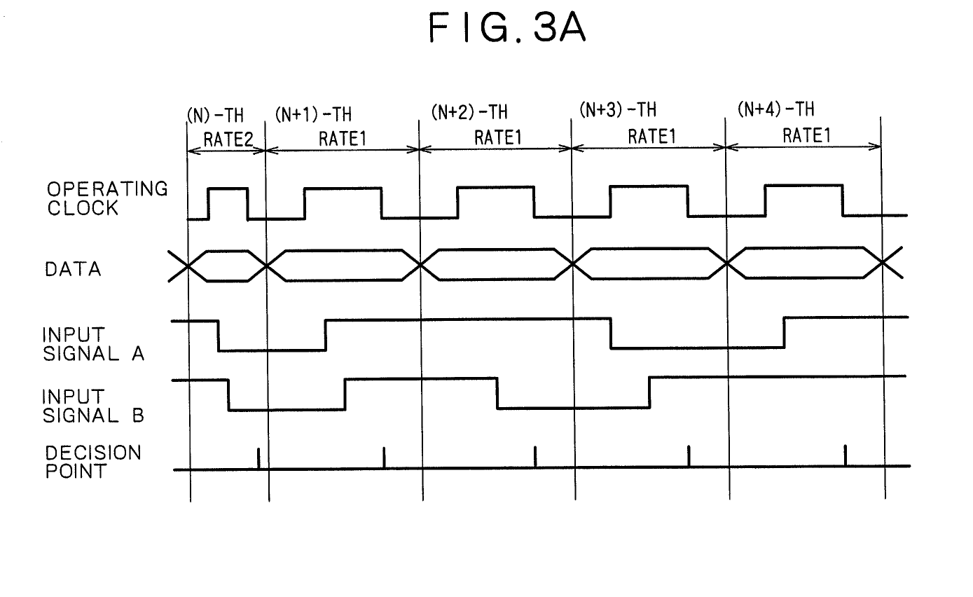

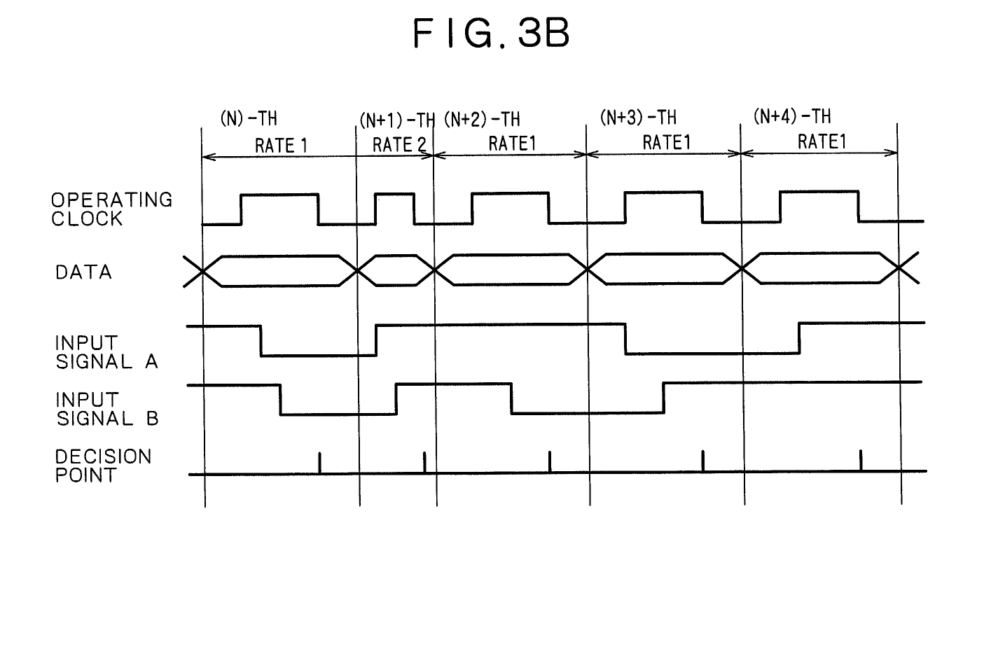

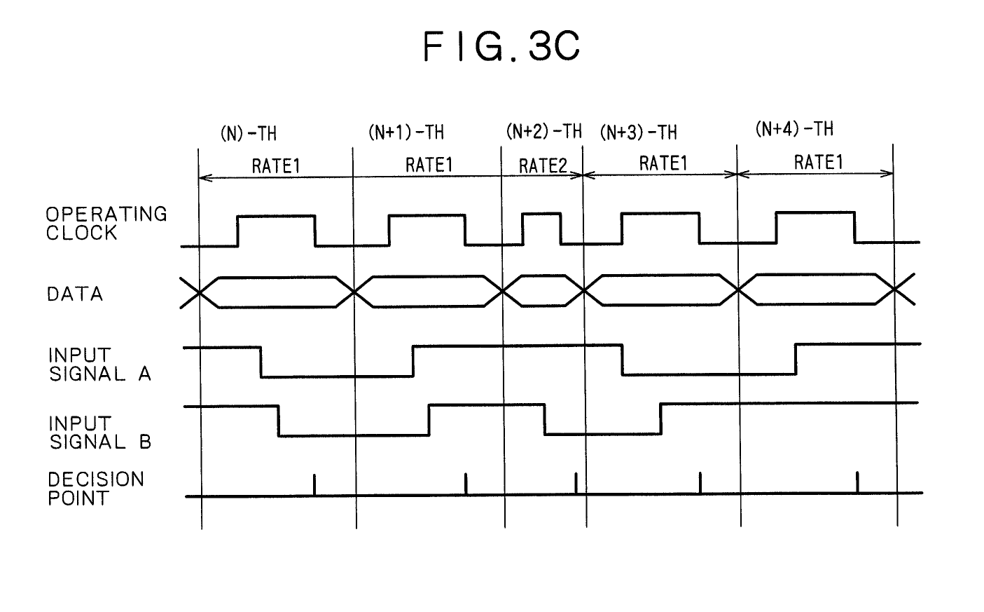

Next, an explanation will be given on a second test which performs an operation of narrowing the rate of only the specific address successively from the top pattern address throughout the entire test pattern in order. FIGS. 3A to 3C are timing charts of the second test executed in the semiconductor testing apparatus which represents an embodiment of the present invention. These timing charts show an example of executing a test by successively narrowing the cycle period rate in a desired pattern address section ranging from an (N)-th pattern address to an (N+4)-th pattern address. In the test of FIG. 3A, the rate of only the (N)-th pattern address is set to a narrow value (RATE 2), while the rate of any other address is set to a wide value (RATE 1) lower than the maximum operation frequency. Subsequently in FIG. 3B, the rate of only the (N+1)-th pattern address is set to RATE 2. And in FIG. 3C, the rate of only the (N+2)-th pattern address is set to RATE 2. As a result of such test where the cycle period rate is narrowed successively, it becomes possible to confirm the specific address that determines the maximum operation frequency.

Further according to the present invention, when the specific address that restricts the maximum operation frequency of the semiconductor device has been detected as mentioned, the operation can be confirmed with facility by widening the rate of this portion alone. For example, in case the (N+3)-th specific address restricts the maximum operation frequency of the semiconductor device, the cycle frequency rate of this (N+3)-th specific address alone is widened to obtain a state with a sufficient margin. Then the cycle frequency rate (RATE 1) of the other addresses is changed to consequently execute the test where the rate of only the address that restricts the maximum operation frequency of the semiconductor device is widened, hence achieving a verification.

The explanation given above is concerned with an exemplary case where two cycle period rates are existent, i.e., the cycle period rate of the specific address and that of the other addresses. However, a plurality of rates may be set as well in compliance with requirements, including a normal state rate, a widened rate and a narrowed rate.

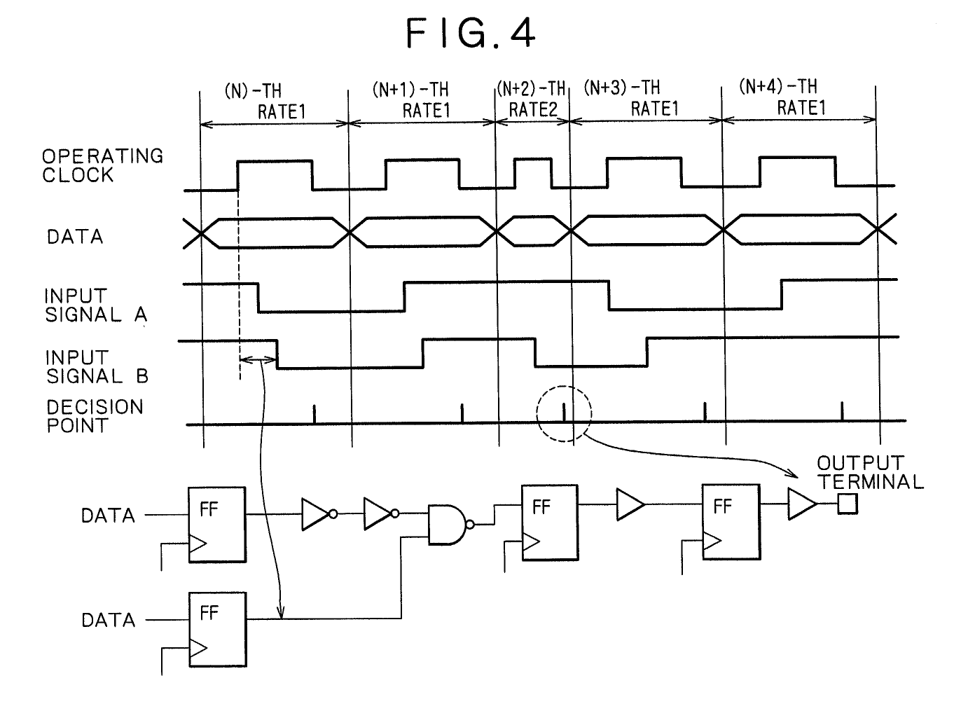

Now the mutual correspondence between the test pattern and the internal circuit of the semiconductor device will be described below. FIG. 4 is a conceptual diagram showing the correspondence between the test pattern and the internal circuit of the semiconductor device. In the semiconductor testing apparatus, there is obtainable merely the signal information at the input and output terminals, and the inside of the semiconductor device is a black box. Therefore, it is difficult to directly analyze or extract the internal information in the semiconductor device, including trouble or fault in any internal circuit portion, or information about any insufficient margin or the like relative to the designed timing in some path. In the example of FIG. 4, the (N+2)-th pattern address is decided as a portion where the signal from the output pin is different from the expected value and is regarded as a fail, but actually, it is in the (N)-th pattern address that the timing margin is insufficient in the internal circuit of the semiconductor device and erroneous data have been inputted. In the present invention, however, the cycle period rate of any pattern address can be variably set, so that the cycle period rates relative to the test patterns of any suspicious address and adjacent addresses thereof may be variably set in the test, and the result may be analyzed to consequently realize acquisition of the information about both of the fail address at the output pin and the actual fail-caused address.

In locating the faulty internal circuit portion after detection of the actual fail-caused address, one of adequate tracking methods may be carried out by preparing some new kinds of trouble-shooting test patterns. In the prior art, it has been customary heretofore to perform an analysis in this manner. It is considered that the work to prepare new test patterns for trouble shooting is not easy particularly in a large-scale circuit configuration.

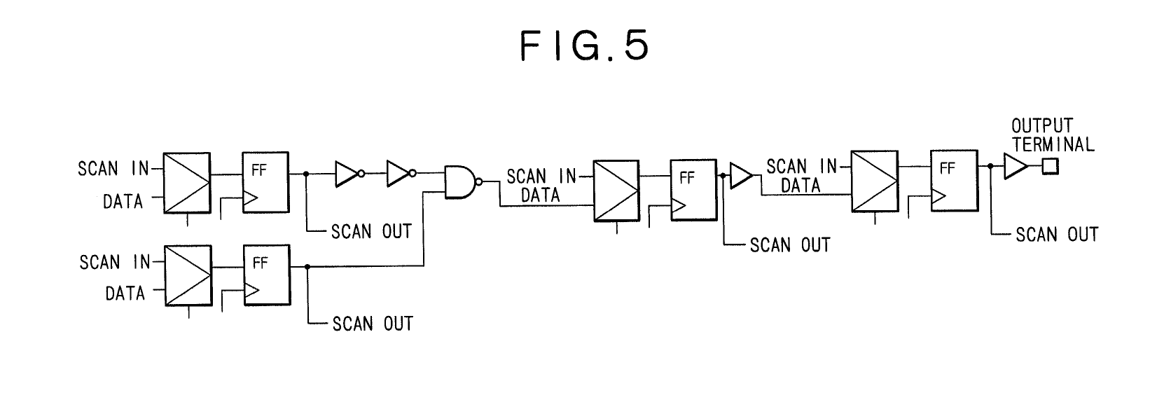

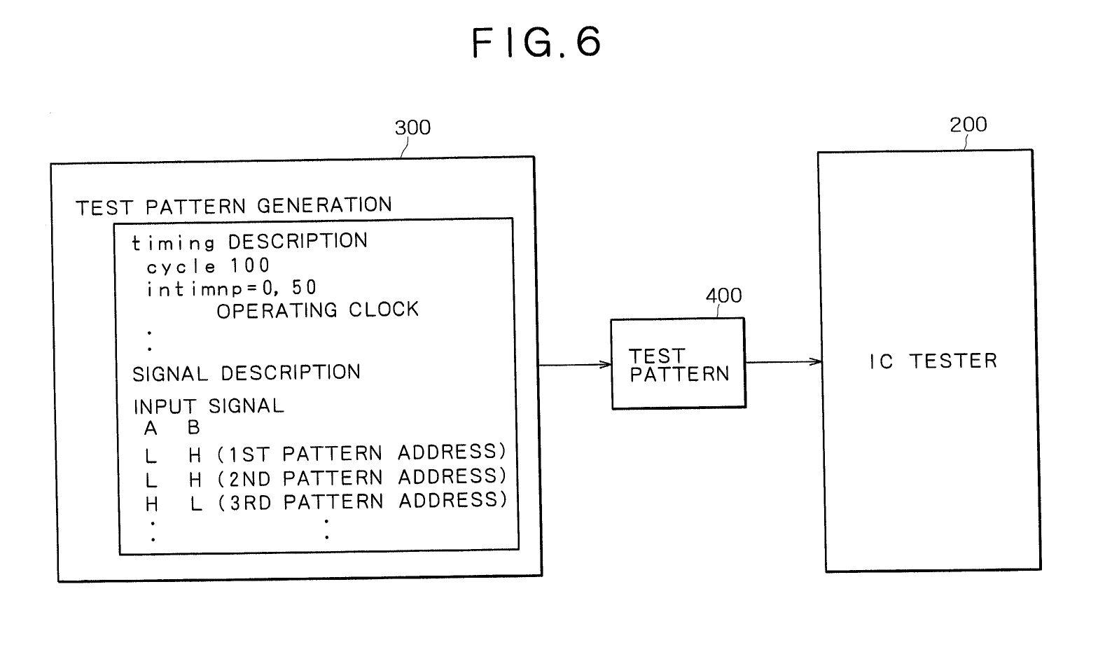

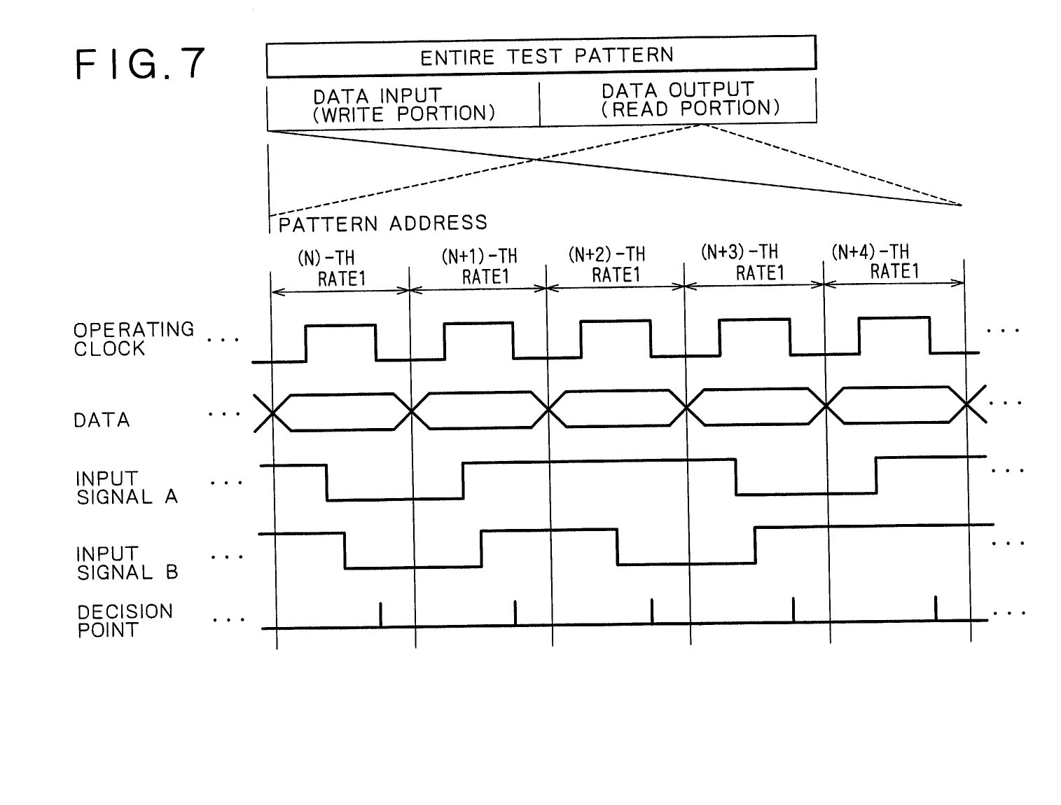

However, according to the present invention, trouble shooting can be achieved with facility. FIG. 5 is a diagram representing an embodiment of a fault analysis technique which employs the semiconductor testing method of the present invention. As shown in this diagram, a scanning path is prepared in the internal circuit of the semiconductor device, and the cycle period of a test pattern for each address is set adequately to locate the fail-caused address. Since any flip-flop state corresponding to the fail-caused address state is determined uniquely, the fail-caused address can be reproduced by supplying data from a scan-in side. And when fail information is read from a scan-out side, it becomes possible to detect which of the flip-flops has the fail cause. By applying this technique, any specific path can be located with facility even in case the input path to the specified flip-flop is branched into a plurality of paths.

Thus, the present invention is capable of specifying any faulty portion in a non-destructive manner faster than any known appliance such as an EB tester or the like which requires processing of a semiconductor device for analysis.

In the semiconductor testing apparatus of the present invention, as described hereinabove, a test pattern for a specified address is outputted at a timing corresponding to set information, in such a manner that the test pattern is supplied to the semiconductor device, which is being tested, at the timing that conforms with the predetermined set information, whereby a test pattern signal is generated on the basis of such test pattern. As a result, the timing to generate the test pattern of the desired address is controlled in conformity with the set information, hence generating a desired test period.

As the timing to generate the test pattern of the desired address is thus controlled, it becomes possible to variably set the cycle period of the test pattern for any specific address, thereby realizing evaluation, analysis and so forth of the semiconductor device where the timing of the specific address is noted. Further, due to such evaluation and analysis of the timing of the specific address that restricts the operation frequency, it becomes possible to obtain effective information for analyzing the internal timing operation, hence achieving a contribution to improvement in the maximum operation frequency of the semiconductor device.

In the semiconductor testing method of the present invention, a test pattern corresponding to the address test pattern data stored previously is outputted in a test at the predetermined timing that conforms to the set information, whereby a test pattern signal is generated on the basis of such test pattern. As a result, the timing to generate the test pattern of the desired address is controlled in conformity with the set information, hence generating a desired test period.

Since the timing to generate the test pattern of the desired address is thus controlled, it becomes possible to set the cycle period of the test pattern for any specific address to a desired period, thereby realizing evaluation, analysis and so forth of the semiconductor device where the timing of the specific address is noted. Further, due to such evaluation and analysis of the timing of the specific address that restricts the operation frequency, it becomes possible to obtain effective information for analyzing the internal timing operation, hence achieving a contribution to improvement in the maximum operation frequency of the semiconductor device.

While a preferred embodiment of the present invention has been described using specific terms, such description is for illustrative purposes only, and it is to be understood that changes and variations may be made without departing from the spirit or scope of the following claims.

What is claimed is:

1. A semiconductor testing apparatus wherein an input signal of a test pattern is supplied to a semiconductor device, and an output signal obtained from said semiconductor device is compared with a prescribed expected value to conduct a test, said apparatus comprising:
test pattern memory means adapted for storing test pattern data of the test pattern, managing the test pattern data in accordance with addresses, and outputting the test pattern specified by any address;
test pattern generation means for generating a test pattern signal on the basis of the test pattern outputted from said test pattern memory means; and
control means for controlling said test pattern memory means and said test pattern generation means in such a manner that the test pattern signal based on the test pattern data of a desired address can be generated at a predetermined timing conforming to the set information.

2. The semiconductor testing apparatus according to claim 1, wherein the contents of said set information are changeable in compliance with requirements, and said control means controls the timing of generation of the test pattern on the basis of the latest changed set information, and varies the cycle period to execute the test pattern of the desired address.

3. The semiconductor testing apparatus according to claim 1, wherein said control means controls the timing of generation of the test pattern in such a manner that the cycle period rate to execute the test pattern of the desired address becomes a cycle period narrower than a predetermined rate.

4. A semiconductor testing method for conducting a test of a semiconductor device by supplying an input signal of a test pattern to said semiconductor device and comparing an output signal therefrom with a prescribed expected value, said method comprising the steps of:
managing and storing, in accordance with addresses, test pattern data of the test pattern generated previously;
outputting the test pattern of a desired address at a predetermined timing that conforms with the set information; and
generating a test pattern signal on the basis of the test pattern data of the desired address outputted at said predetermined timing.

5. The semiconductor testing method according to claim 4, further comprising the steps of:
supplying the input signal of the test pattern to said semiconductor device after variably setting the desired address and the predetermined timing; and
detecting whether any failure has been caused or not in said semiconductor device, thereby analyzing the internal fault in said semiconductor device.
